(19) United States
(12) Patent Application Publication
(10) Pub. No.: US 2015/0211698 A1
(43) Pub. Date: Jul. 30, 2015

(54) LIGHT BAR STRUCTURE, LIGHT SOURCE MODULE AND LAMP

(71) Applicant: Radiant Opto-Electronics Corporation, Kaohsiung (TW)

(72) Inventors: Hsiu-Hung YEH, KAOHSIUNG (TW); Chih-Hsien CHUNG, KAOHSIUNG (TW)

(21) Appl. No.: 14/326,521

(22) Filed: Jul. 9, 2014

(30) Foreign Application Priority Data
Jan. 28, 2014 (TW) 103103237

(51) Int. Cl. F21S 4/00; F21V 23/00; F21V 8/00; F21V 23/06; H05K 1/18

(52) U.S. Cl. CPC F21S 4/008; F21V 23/06; H05K 1/189; G02B 6/009; F21V 23/009; F21V 23/008; F21Y 2103/003

(57) ABSTRACT

A light bar structure, a light source module and a lamp are provided. The light bar structure includes a substrate, an electrical unit and light-emitting diodes. The substrate includes a first surface. The electrical unit includes a light-source disposing portion, at least one flexible connector and at least one electrical connection end. The light light-source disposing portion is connected to the first surface of the substrate. One end of the flexible connector is connected to the light-source disposing portion. The electrical connection end is correspondingly connected to the other end of the flexible connector. The electrical connection end is disposed on a position of the flexible connector away from the first surface of the substrate. The light-emitting diodes are disposed on the light-source disposing portion.

### RELATED APPLICATIONS

This application claims priority to Taiwan Application Serial Number 103103237, filed Jan. 28, 2014, which is herein incorporated by reference.

### BACKGROUND

1. Field of Invention

The present invention relates to a light source device. More particularly, the present invention relates to a light bar structure, a light source module and a lamp.

2. Description of Related Art

Light source modules are widely used in backlight modules or lamps. Referring to FIG. 1, FIG. 1 is a schematic structural diagram showing a conventional light source module 200. The conventional light source module 200 includes a carrier 210, a light bar 230 and a light guide plate 250. The carrier 210 has a flange wall 210a and a bottom surface 210b. The light bar 230 is fixed on the flange wall 210a by using a screwing member 270 screwed in laterally, so as to emit light towards the light guide plate 250. In addition, connectors 290 are disposed on two ends of the light bar 230 for connecting to an external power source or other driving circuits.

However, the light source module 200 has many disadvantages, for example, because the light bar 230 is limited by the connectors 290 disposed on its both ends, the light source (the light bar 230) cannot be effectively utilized. Moreover, because the light bar 230 is disposed on the flange wall 210a, heat generated by the light bar 230 has to first pass through the flange wall 210a to the bottom surface 210b, and then is transferred to the ambience, and thus the light source module 200 has poor heat dissipation efficacy. Furthermore, for disposing the connectors 290, a certain width of the light bar 230 has to be kept, which is disadvantageous to reducing the overall width of the light source module 200.

Hence, the application of the light source module 200 to a backlight module is disadvantageous to the structural design of a narrow frame. Moreover, the connectors 290 disposed on the both ends of the light bar may result in dark stripes appearing near the frame, thus seriously affecting the optical effect. When being applied to the lamp, the light source module 200 would limit the structural design of the lamp, thus affecting the requirements of lightness, thinness and appealing appearance of the lamp.

### SUMMARY

One aspect of the present invention is to provide a light bar structure, a light source module and a lamp, in which a position of an electrical connection end of the light bar structure can be flexibly adjusted to reduce a width or height of the light bar structure to meet the requirements of narrow frame backlight module. Moreover, when being applied to the lamp, the light bar structure of the present invention can be designed corresponding to different structures of frames for achieving the objects of thinness, lightweight and appealing appearance. In addition, the light bar structure of the present invention is directly disposed on a carrier to replace the flange wall of the conventional carrier, thereby increasing available space on the carrier and simplifying the assembling processes of the light source module.

According to the aforementioned objects, a light bar structure is provided. The light bar structure includes a substrate, an electrical unit and light-emitting diodes. The substrate includes a first surface. The electrical unit includes a light-source disposing portion, at least one flexible connector and at least one electrical connection end. The light-source disposing portion is connected to the first surface of the substrate. One end of the flexible connector is connected to the light-source disposing portion. The electrical connection end is correspondingly connected to the other end of the flexible connector, in which the electrical connection end is located on a position of the flexible connector away from the first surface of the substrate. The light-emitting diodes are disposed on the light-source disposing portion.

According to an embodiment of the present invention, the substrate is made of metal.

According to an embodiment of the present invention, the electrical unit is a flexible printed circuit board (FPCB).

According to an embodiment of the present invention, the electrical connection end is a connector-type electrical connection or gold-fingers type electrical connection.

According to an embodiment of the present invention, the further includes a second surface opposite to the first surface, and the electrical connection end is disposed on the second surface.

According to an embodiment of the present invention, a light source module is provided. The light source module includes a carrier, a light guide plate and a light bar structure. The light guide plate is disposed on the carrier and has a light-incident surface. The light, bar structure is adjacent to the light-incident surface and includes a substrate, an electrical unit and light-emitting diodes. The substrate includes a first surface. The electrical unit includes a light-source disposing portion, at least one flexible connector and at least one electrical connection end. The light-source disposing portion is connected to the first surface of the substrate. One end of the flexible connector is connected to the light-source disposing portion. The electrical connection end is correspondingly connected to the other end of the flexible connector, in which the electrical connection end is located on a position of the flexible connector away from the first surface of the substrate. The ht-emitting diodes are disposed on the light-source disposing portion.

According to an embodiment of the present invention, the carrier has a holding surface, and the substrate further includes a second surface opposite to the first surface and a third surface opposite to the holding surface, in which the third surface connects the first surface and the second surface.

According to an embodiment of the present invention, the light bar structure includes at least one securing member penetrating through the substrate from the third surface so as to fix the substrate on the holding surface.

According to an embodiment of the present invention, the light bar structure includes an adhesive member used to fix the substrate on the holding surface.

According to an embodiment of the present invention, the light bar structure includes a welding layer used to fix the substrate on the holding surface.

According to an embodiment of the present invention, the substrate includes a second surface opposite to the first surface, and the electrical connection end is disposed on the second surface.

According to an embodiment of the present invention, the carrier includes a bottom surface opposite to the holding surface, and the electrical connection end is disposed on the bottom surface.

According to an embodiment of the present invention, a lamp is provided. The lamp includes a housing, a light guide plate, a light bar structure and a controlling unit. The light guide plate is disposed on the housing and has a light-incident surface. The light bar structure is adjacent to the light-incident surface and includes a substrate, an electrical unit and light-emitting diodes. The substrate includes a first surface. The electrical unit includes a light-source disposing portion, at least one flexible connector and at least one electrical connection end. The light-source disposing portion is connected to the first surface of the substrate. One end of the flexible connector is connected to the light-source disposing portion. The electrical connection end is correspondingly connected to the other end of the flexible connector, in which the electrical connection end is located on a position of the flexible connector away from the first surface of the substrate. The light-emitting diodes are disposed on the light-source disposing portion. The controlling unit is electrically connected to the electrical connection end.

According to an embodiment of the present invention, the controlling unit includes a driving circuit and a controlling circuit.

According to an embodiment of the present invention, the controlling unit is disposed outside the housing independently.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic structural diagram showing a conventional light source module;

FIG. 2 is a schematic structural diagram showing a light source module in accordance with a first embodiment of the present invention;

FIG. 3 is a schematic structural diagram showing a light bar structure in accordance with the first embodiment of the present invention;

FIG. 4 is a schematic structural diagram showing another light bar structure in accordance with the first embodiment of the present invention;

FIG. 5 is a schematic structural diagram showing a connector-type electrical connection end in accordance with the first embodiment of the present invention;

FIG. 6A is a schematic structural diagram showing a light source module in accordance with a second embodiment of the present invention;

FIG. 6B is a schematic structural diagram showing a light source module in accordance with a third embodiment of the present invention;

FIG. 7 is a schematic diagram showing a light bar structure disposed on a bottom surface of a carrier in accordance with one embodiment of the present invention; and

FIG. 8 is a schematic structural diagram showing a lamp in accordance with one embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

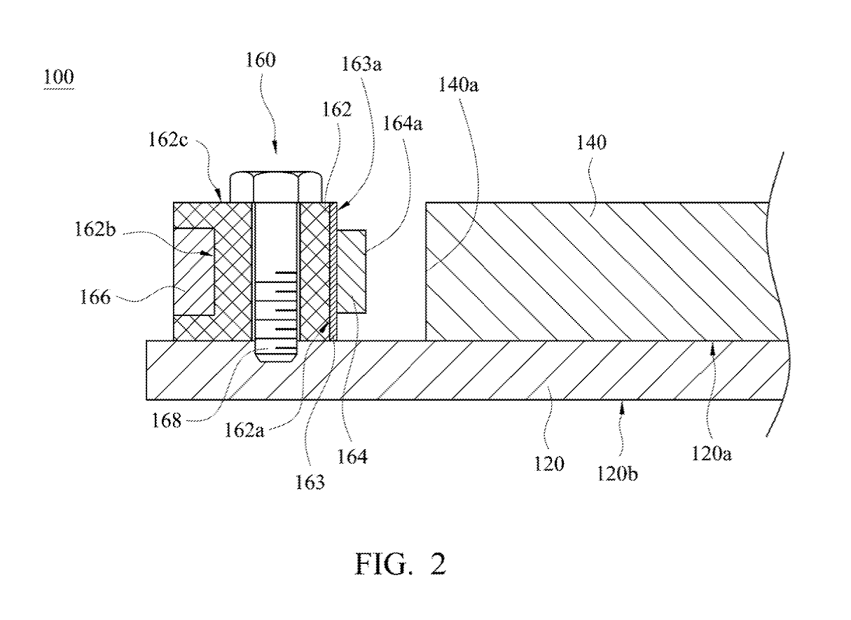

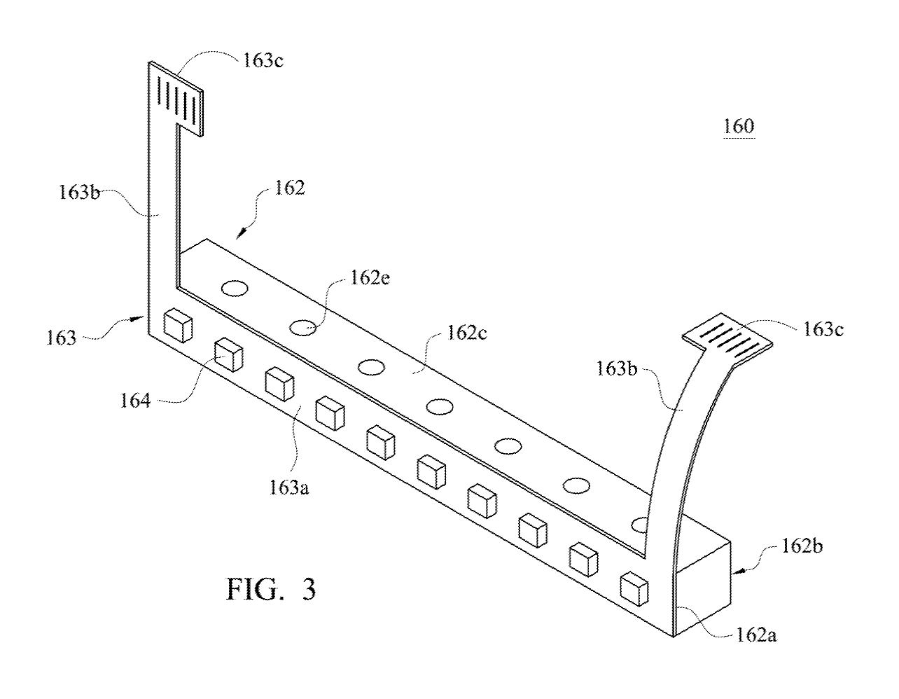

Referring to FIG. 2 and FIG. 3, FIG. 2 is a schematic structural diagram showing a light source module 100 in accordance with a first embodiment of the present invention, and FIG. 3 is a schematic structural diagram showing a light bar structure 160 in accordance with the first embodiment, of the present invention. In the present embodiment, the light source module 100 is applicable to a backlight module or a lamp. The light source module 100 includes a carrier 120, a light guide plate 140 and the light bar structure 160. The light guide plate 140 and the light bar structure 160 are disposed on the carrier 120. The light guide plate 140 includes a light-incident surface 140a. The light bar structure 160 is disposed by the light-incident surface 140a of the light guide plate 140, and light generated by the light bar structure 160 may enter the light guide plate 140 from the light-incident surface 140a. It is noted that, when the light source module 100 is applied to the backlight module, the carrier 120 can be referred as a back plate. In addition, when the light source module 100 is applied to the lamp, the carrier 120 can be referred as a frame or a casing, in which the frame or the casing can be designed according to the location of a light-emitting surface or other design requirements.

Referring to FIG. 2 and FIG. 3 again, the light bar structure 160 includes a substrate 162, an electrical unit 163 and light-emitting diodes 164. The electrical unit 163 is disposed on the substrate 162 and includes a light-source disposing portion 163a, at least one flexible connector 163b and at least one electrical connection end 163c. The light-emitting diodes 164 are disposed on the light-source disposing portion 163a of the electrical unit 163. One end of the flexible connector 163b is connected to the light-source disposing portion 163a, the electrical connection end 163c is correspondingly connected to the other end of the flexible connector 163b. Therefore, the electrical connection end 163c can be disposed at any portion of the light source module 100 corresponding to structural design of the light source module 100 through the flexible connector 163b. In addition, the electrical connection end 163c can be an interface for external power connection. For example, the electrical connection end 163c can electrically connect the light-emitting diodes 164 to a power source or other driving circuit systems.

As shown in FIG. 2, the carrier 120 has holding surface 120a. In one embodiment, a shape of the substrate 162 can be designed corresponding a shape of the light guide plate 140. Moreover, the substrate 162 further includes a first surface 162a, a second surface 162b and a third surface 162c, in which the second surface 162b is opposite to the first surface 162a. The third surface is opposite to the holding surface 120a and connects the first surface 162a and the second surface 162b. In one embodiment, the substrate 162 may be a metal substrate, for example, an aluminum substrate. In addition, the light-source disposing portion 163a of the electrical unit 163 is disposed on the first surface 162a, and the electrical connection end 163c is located on the end of the flexible connector 163b away from the first surface 162a or any surface other than the first surface 162a. The light-emitting diodes 164 are disposed on the light-source disposing portion 163a, and each of the light-emitting diodes 164 has a light-emitting surface 164a. When the light bar structure 160 is disposed on the carrier 120, the light-emitting surface 164a faces the light-incident surface 140a of the light guide plate 140.

Referring to FIG. 2 and FIG. 3 again, in one embodiment, the light bar structure 160 further includes at least one securing member 168, and the substrate 162 further includes a securing hole 162e penetrating through the substrate 162 from the third surface 162c. The substrate 162 can be fixed on the holding surface 120a of the carrier 120 through the securing member 168. In other words, the securing member 168 can be screwed into the substrate 162 along a direction vertical to the carrier 120 to fix the substrate 162 on the carrier 120.

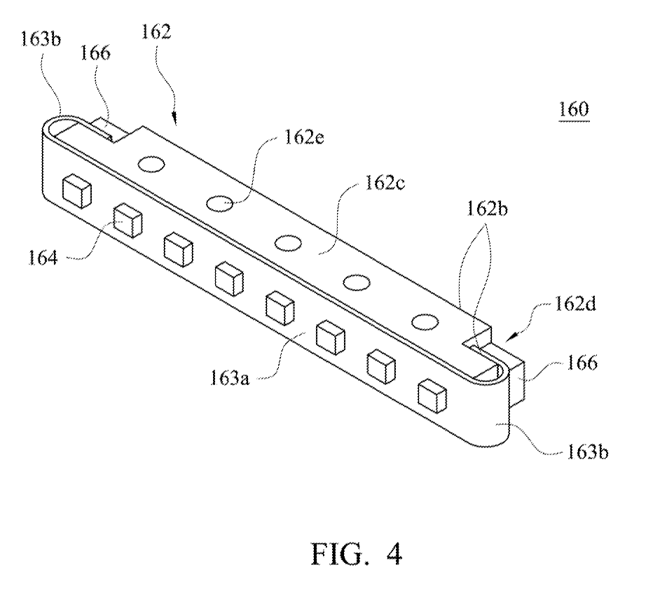

In addition, the light bar structure of the present invention has different designs. Simultaneously referring to FIG. 3 and FIG. 4, FIG. 4 is a schematic structural diagram showing another light bar structure in accordance with the first embodiment of the present invention. The flexible connector 163b of the light bar structure 160 shown in FIG. 3 extends along a direction vertical to a long side of the substrate 162. In other embodiment, as shown in FIG. 4, the flexible connector 163b extends along a direction parallel to the long side of the substrate 162. In one embodiment, the flexible connector 163b is a flexible printed circuit board.

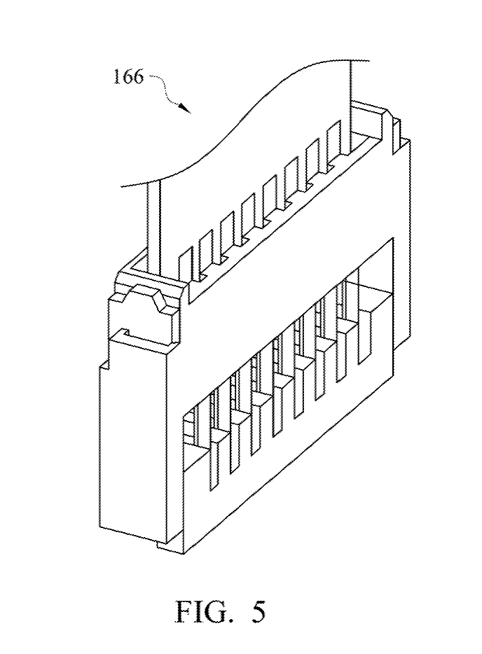

Simultaneously referring to FIG. 5, FIG. 5 is a schematic structural diagram showing a connector-type electrical connection end in accordance with the first embodiment of the present invention. It is noted that a gold-fingers type electrical connection end shown in FIG. 3 is merely used as an example for explanation in the present embodiment, and the present invention is not limited thereto. In other embodiments, the electrical connection end 163c is a connector-type electrical connection end 166. Simultaneously referring to FIG. 4 and FIG. 5, the electrical connection end 166 is disposed on the second surface 162b of the substrate 162. Moreover, the substrate 162 includes a recess 162d recessed into the second surface 162b, in which the recess 162d is used to accommodate the connector-type electrical connection end 166, thus reducing occupied size of the light bar structure 160.

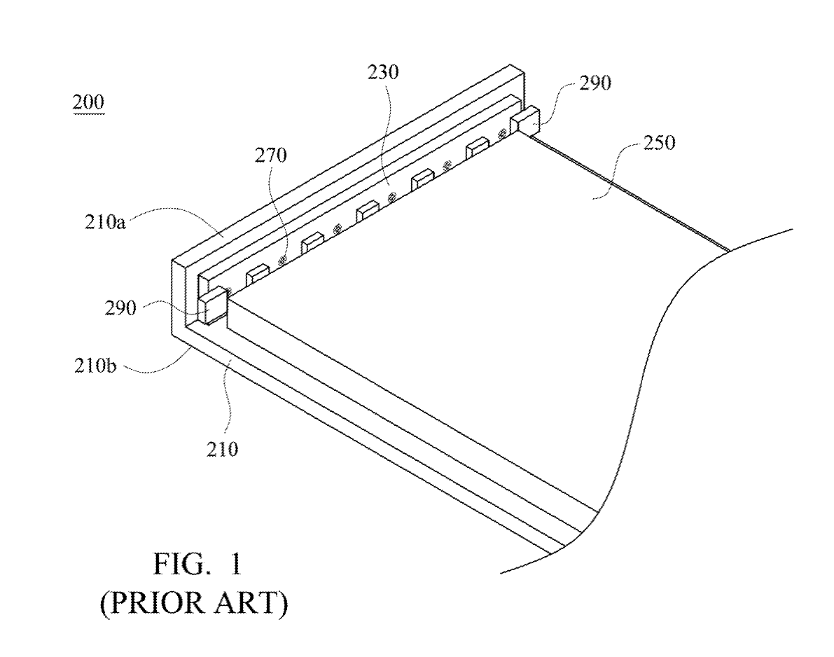

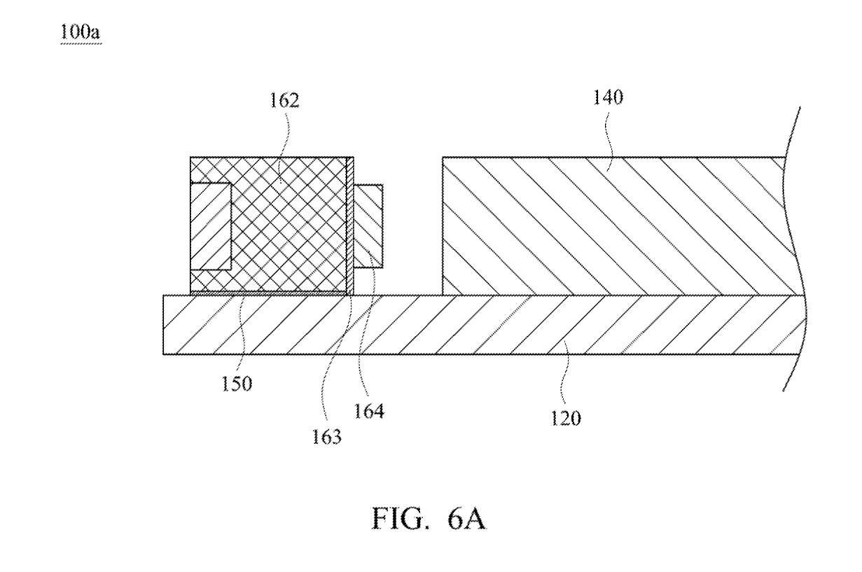

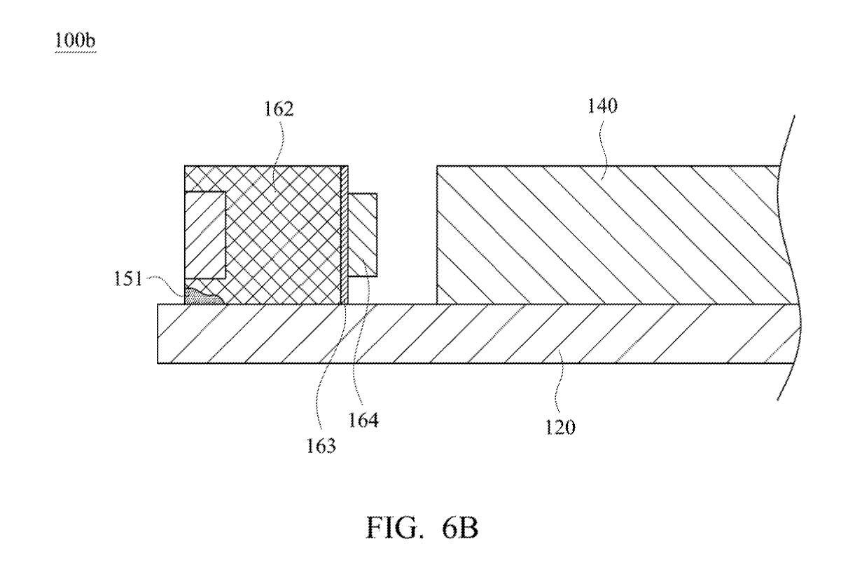

It is noted that the substrate 162 shown in FIG. 2 is fixed on the carrier 120 through the securing member, but the present invention is not limited thereto. Referring to FIGS. 6A and 6B, FIG. 6A is a schematic structural diagram showing a light source module 100a in accordance with a second embodiment of the present invention, and FIG. 6B is a schematic structural diagram showing a light source module 100b in accordance with a third embodiment of the present invention. In some embodiments, the substrate 162 of the light source module 100a shown in FIG. 6A can be adhered on the carrier 120 through an adhesive member 150 without disposing the securing hole 162e on the substrate 162. In other embodiments, the substrate 162 of the light source module 100b shown in FIG. 6B can be welded on the carrier 120 through a welding layer 151 without disposing the securing hole 162e on the substrate 162. Therefore, whether the substrate 162 is fixed on the carrier 120 by a screwing manner, an adhesive manner or a welding manner, heat generated by the light-emitting diodes 164 can be quickly transferred to the ambience through the carrier 120. Moreover, the carrier 120 does not need to have the flange wall 210a of the conventional L-shaped carrier 210 shown in FIG. 1, such that more available space on the carrier 120 can be obtained. In addition, the substrate can be directly used to replace the flange wall 210a of the carrier 210, so as to simplify the assembling processes of the light source module 100.

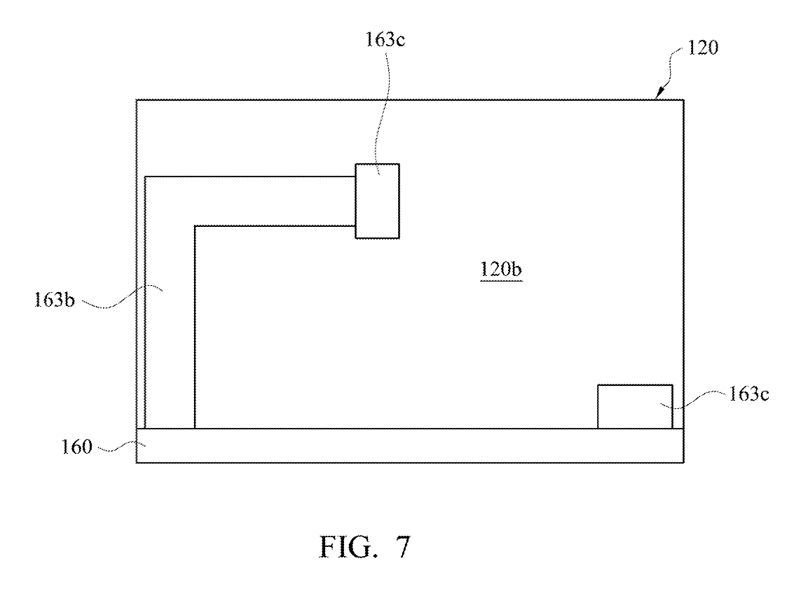

Simultaneously referring to FIG. 2 and FIG. 7, FIG. 7 is a schematic diagram showing a light bar structure disposed on a bottom surface of a carrier in accordance with one embodiment of the present invention. In one embodiment, the carrier 120 further includes a bottom surface 120b opposite to the holding surface 120a. Moreover, the electrical connection end 163c can be extended to the bottom surface 120b (or back side) of the carrier 120 or to any position away from the light bar structure 160 based on the length of the flexible connector 163b, Therefore, the position of the electrical connection end 163c can be adjusted by changing the form of the flexible connector 163b, so as to match structural design of back light modules or lamps. It is noted that lengths and extending directions of the flexible connector 163b shown in FIG. 3, FIG. 4 and FIG. 7 are merely used as different examples for explanation, and the present invention is not limited thereto. The length, extending direction of the flexible connector 163b or the position of the flexible connector 163b connected to the light-source disposing portion 163a can be adjusted to meet the usage requirements.

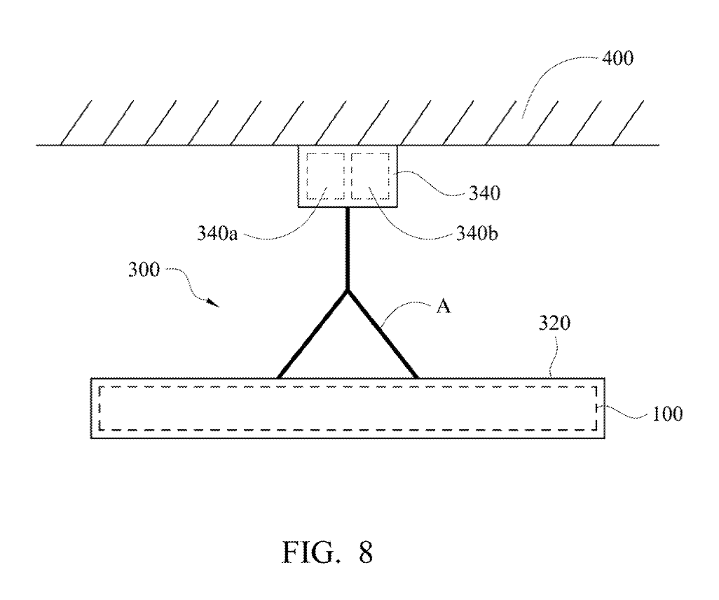

Simultaneously referring to FIG. 2 and FIG. 8, FIG. 8 is a schematic structural diagram showing a lamp 300 in accordance with one embodiment of the present invention. The lamp 300 includes a housing 320, the light source module 100 shown in FIG. 2 and a controlling unit 340. The light source module 100 is disposed on the housing 320, and the controlling unit 340 is electrically connected to the light-emitting diodes 164 of the light source module 100, in which the so-called “electrically connected” means that the electrical connection end 166 of the light source module 100 and an electric wire are used to connect the light-emitting diodes 164 to the controlling unit 340. In one embodiment, the controlling unit 340 is disposed outside the housing 320 independently. As shown in FIG. 8, when the lamp 300 is hung on the ceiling 400 through a rope A, the controlling unit 340 can be separately disposed on the ceiling 400. In addition, the controlling unit 340 includes a driving circuit 340a and a controlling circuit 340b, so as to turn on/off the light source module 100.

According to the aforementioned embodiments of the present invention, the position of the electrical connection end can be adjusted by using the flexible connector, so as to dispose the electrical connection end on the back side of the substrate, the bottom surface of the carrier or any position away from the substrate, thus achieving the objects of reducing the width of the light bar structure to meet the requirements of narrow frame backlight module. In addition, when being applied to a lamp, the light bar structure of the present invention can be designed corresponding to various frame structures, thus achieving the objects of thinness, lightweight and appealing appearance. Moreover, the light bar structure of the present invention is disposed on the carrier, and the substrate can be used to replace the flange wall of the conventional carrier, thus increasing the available space on the carrier and simplifying the assembling processes of the light source module. Furthermore, heat generated by the light-emitting diodes can be directly transferred to the ambience through the carrier, thus promoting the heat dissipation efficacy of the light source module.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light bar structure, comprising:
a substrate comprising a first surface;
an electrical unit comprising:
a light-source disposing portion connected to the first surface of the substrate;
at least one flexible connector of which one end is connected to the light-source disposing portion; and
at least one electrical connection end correspondingly connected to the other end of the at least one flexible connector, wherein the at least one electrical connection end is located on a position of the at least one flexible connector away from the first surface of the substrate; and
a plurality of light-emitting diodes disposed on the light-source disposing portion.

2. The light bar structure of claim 1, wherein the substrate is made of metal.

3. The light bar structure of claim 1, wherein the electrical unit is a flexible printed circuit board (FPCB).

4. The light bar structure of claim 1, wherein at least one electrical connection end is a connector-type electrical connection or gold-fingers type electrical connection.

5. The light bar structure of claim 1, wherein the substrate further comprises a second surface opposite to the first surface, and the at least one electrical connection end is disposed on the second surface.

6. A light source module, co rising:
a carrier;
a light guide plate which is disposed on the carrier and has a light-incident surface; and
a light bar structure which is adjacent to the light-incident surface and comprises:
a substrate comprising a first surface;
an electrical unit comprising:
a light-source disposing portion connected to the first surface of the substrate;
at least one flexible connector of which one end is connected to the light-source disposing portion; and
at least one electrical connection end correspondingly connected to the other end of the at least one flexible connector, wherein the at least one electrical connection end is disposed on a position of the at least one flexible connector away from the first surface of the substrate; and
a plurality of bight-emitting diodes disposed on the light-source disposing portion.

7. The light source module of claim 6, wherein the carrier has a holding surface, and the substrate further comprises a second surface opposite to the first surface and a third surface opposite to the holding surface, wherein the third surface connects the first surface and the second surface.

8. The light source module of claim 7, wherein the light bar structure comprises at least one securing member penetrating through the substrate from the third surface so as to fix the substrate on the holding surface.

9. The light source module of claim 7, wherein the light bar structure comprises an adhesive member used to fix the substrate on the holding surface.

10. The light source module of claim 7, wherein the light bar structure comprises a welding layer used to fix the substrate on the holding surface.

11. The light source module of claim 6, wherein the substrate comprises a second surface opposite to the first surface, and the at least one electrical connection end is disposed on the second surface.

12. The light source module of claim 6, wherein the carrier comprises a bottom surface opposite to the holding surface, and the at least one electrical connection end is disposed on the bottom surface.

13. A lamp, comprising:
a housing;
a light guide plate which is disposed on the housing and has a light-incident surface;
a light bar structure which is adjacent to the light-incident surface and comprises:
a substrate comprising a first surface;
an electrical unit comprising:
a light-source disposing portion connected to the first surface of the substrate;
at least one flexible connector of which one end is connected to the light-source disposing portion; and
at least one electrical connection end correspondingly connected to the other end of the at least one flexible connector, wherein the at least one electrical connection end is disposed on a position of the at least one flexible connector away from the first surface of the substrate; and
a plurality of light-emitting diodes disposed on the light-source disposing portion; and
a controlling unit electrically connected to the at least one electrical connection end.

14. The lamp of claim 13, wherein the controlling unit comprises a driving circuit and a controlling circuit.

15. The lamp of claim 13, wherein the controlling unit is disposed outside the housing independently.
